(19) United States
(12) Patent Application Publication
(10) Pub. No.: US 2016/0282730 A1
(43) Pub. Date: Sep. 29, 2016

(54) SEMICONDUCTOR DEVICE, METHOD OF MANUFACTURING THE SAME, AND PATTERN OVERLAY INSPECTION METHOD

(71) Applicant: RENESAS ELECTRONICS CORPORATION, Tokyo (JP)

(72) Inventor: Hironao SASAKI, Ibaraki (JP)

(21) Appl. No.: 15/076,445

(22) Filed: Mar. 21, 2016

(30) Foreign Application Priority Data
Mar. 23, 2015 (JP) 2015-059670

(51) Int. Cl. G03F 9/00; H01L 23/528; G01B 11/27; H01L 21/027; H01L 21/66; H01L 23/522; H01L 21/762

(52) U.S. Cl. CPC G03F 9/7003; H01L 23/5226; H01L 23/528; H01L 21/762; H01L 21/0273; H01L 22/12; G01B 11/272

(57) ABSTRACT

Measurement is made on overlay error amounts of a comparison pattern and reference patterns formed respectively in a plurality of layers. Overlay inspection is performed on the comparison pattern and the reference patterns, based on the measured overlay error amounts of the comparison pattern and the reference patterns.

### CROSS-REFERENCE TO RELATED APPLICATIONS

The disclosure of Japanese Patent Application No. 2015-059670 filed on Mar. 23, 2015 including the specification, drawings and abstract is incorporated herein by reference in its entirety.

### BACKGROUND

The present invention relates to a semiconductor device, and, more particularly, to a method of measuring the overlay of a plurality of pattern layers.

In recent years, the image plane phase detection auto-focus system has spread, as a digital camera auto-focus mechanism using pixels of image sensors. This system has many advantages. Particularly, high-speed distance measurement is possible, since there is no need to drive the lens at the distance measurement. In addition, electric power saving and distance measurement in an arbitrary position of the screen are also possible. On the other hand, it is known that the accuracy of the distance measurement is deteriorated due to an optical axis deviation between the center of a micro lens and the center of a pixel.

Generally, in a manufacturing process for the image sensor, the micro lenses and the uppermost wiring layer are superposed. To suppress the above optical axis deviation, it is necessary to accurately superpose the uppermost wiring layer and the pixels.

On the other hand, to prevent the circuit disconnection, it is necessary to manage the overlay of the wiring layer and a via (vias) (hole layer) right thereunder.

Thus, in the manufacturing process for the image sensor having the image plane phase detection auto-focus function, it is necessary to manage the overlay of the uppermost wiring layer both with the vias (hole layer) right thereunder and the pixels.

As the background art of the present technical field, there is provided Japanese Unexamined Patent Publication No. 2001-267202. Japanese Unexamined Patent Publication No. 2001-267202 discloses a technique for reducing the occupying area of the inspection mark. Specifically, only one inspection mark is used for overlay inspection for a plurality of layers, by forming a mark of a reference layer as an overlay inspection mark in a plurality of ground layers.

Japanese Unexamined Patent Publication No. 2003-272993 discloses a technique for executing mutual overlay inspection for patterns of a plurality of masks, that is, a plurality of comparison layers and reference layers, using one inspection mark.

Japanese Unexamined Patent Publication No. 2004-103797 discloses a technique for executing overlay inspection for a plurality of reference layers using one mark, by forming a plurality of reference layers of the overlay inspection mark to be nested.

An important matter, in the point of performance or reliability of semiconductor products, is to perform high accuracy overlay measurement for patterns formed in a plurality of layers, like an example of an image sensor having the image plane phase detection auto-focus function.

In the manufacturing process for the semiconductor products, the overlay of the patterns in the plurality of layers is measured with high accuracy. When an overlay error occurs therebetween, it is important to feedback (correct) the overlay error in a preceding/following process, in terms of the manufacturing yield of the semiconductor products.

Other objects and new features will be apparent from the descriptions of the present specification and the accompanying drawings.

### SUMMARY

According to one aspect, measurement is made on overlay error amounts of a comparison pattern and reference patterns formed in a plurality of layers, and overlay inspection is performed on the comparison pattern and the reference patterns, based on the measured overlay error amounts of the comparison pattern and the reference patterns.

According to the one aspect, it is possible to perform accurate overlay inspection for the patterns formed in the plurality of layers.

### BRIEF DESCRIPTION OF DRAWINGS

FIG. 1A is a plan view illustrating an example of an overlay inspection mark.

FIG. 1B is a cross sectional view illustrating an example of overlay error measurement, using the overlay inspection mark.

FIG. 2A is a schematic diagram illustrating a state in which an image of the overlay inspection mark is acquired.

FIG. 2B is a schematic diagram illustrating a state in which an image of the overlay inspection mark is acquired.

FIG. 3 is a cross sectional view illustrating a vertical structure of an image sensor according to an embodiment of the present invention.

FIG. 4 is a cross sectional view illustrating a vertical structure of an overlay inspection mark and the image sensor, according to the embodiment of the present invention.

FIG. 5 is a flowchart illustrating an overlay inspection method, according to the embodiment of the present invention.

FIG. 6 is a flowchart illustrating an overlay inspection method, according to the embodiment of the present invention.

FIG. 7A is a diagram illustrating an example of inspection shot layout in a wafer.

FIG. 7B is a diagram illustrating an example of inspection mark layout in an inspection shot.

FIG. 7C is a diagram illustrating an example of inspection patterns in an inspection mark.

FIG. 8 is a diagram illustrating an example of an overlay error of patterns of a plurality of layers.

FIG. 9 is a flowchart illustrating a process flow of a sample wafer according to the embodiment of the present invention.

FIG. 10A is a diagram illustrating an example of a reduction result of the overlay error.

FIG. 10B is a diagram illustrating an example of a reduction result of the overlay error.

FIG. 11A is a cross sectional view illustrating a part of a manufacturing process for a semiconductor device according to the embodiment of the present invention.

FIG. 11B is a cross sectional view illustrating a part of the manufacturing process for the semiconductor device according to the embodiment of the present invention.

FIG. 11C is a cross sectional view illustrating a part of the manufacturing process for the semiconductor device according to the embodiment of the present invention.

FIG. 11D is a cross sectional view illustrating a part of the manufacturing process for the semiconductor device according to the embodiment of the present invention.

FIG. 11E is a cross sectional view illustrating a part of the manufacturing process for the semiconductor device according to the embodiment of the present invention.

FIG. 12A is a plan view illustrating an overlay inspection mark according to the embodiment of the present invention.

FIG. 12B is a schematic diagram illustrating a state in which an image of the overlay inspection mark is acquired, according to the embodiment of the present invention.

FIG. 13A is a cross sectional view illustrating a part of the manufacturing process for the semiconductor device according to the embodiment of the present invention.

FIG. 13B is a cross sectional view illustrating a part of the manufacturing process for the semiconductor device according to the embodiment of the present invention.

FIG. 13C is a cross sectional view illustrating a part of the manufacturing process for the semiconductor device according to the embodiment of the present invention.

FIG. 13D is a cross sectional view illustrating a part of the manufacturing process for the semiconductor device according to the embodiment of the present invention.

FIG. 13E is a cross sectional view illustrating a part of the manufacturing process for the semiconductor device according to the embodiment of the present invention.

FIG. 13F is a cross sectional view illustrating a part of the manufacturing process for the semiconductor device according to the embodiment of the present invention.

### DETAILED DESCRIPTION

Descriptions will now specifically be made to embodiments of the present invention.

### First Embodiment

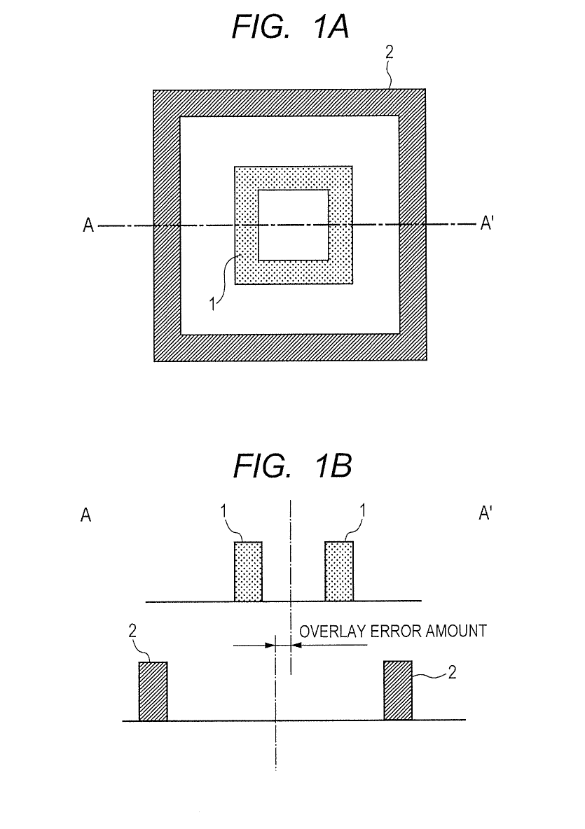

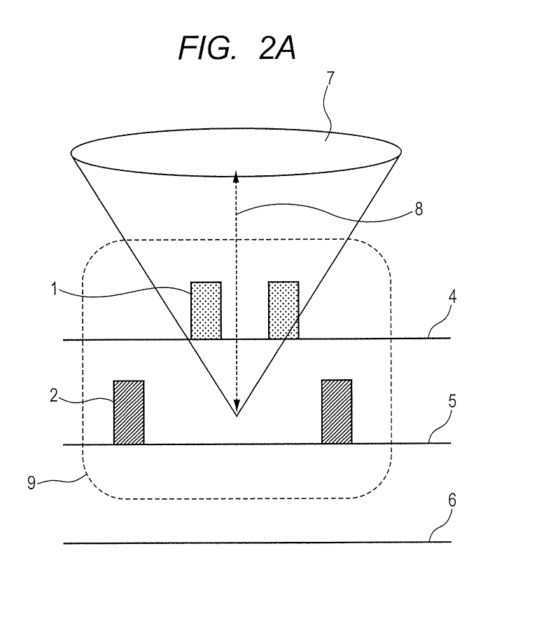

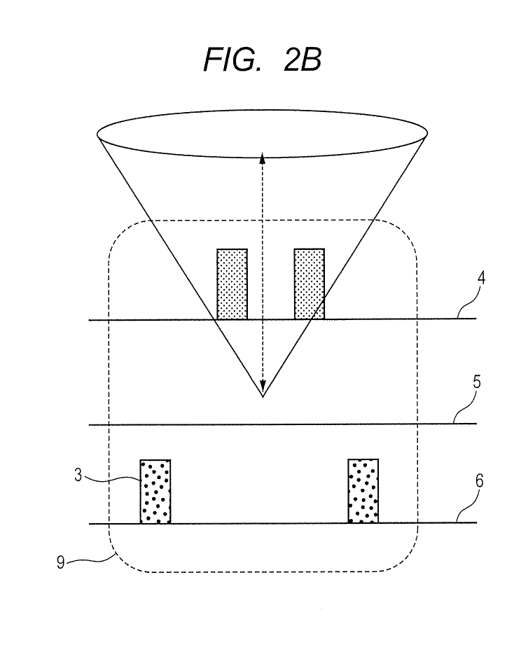

Descriptions will now be made to overlay management of patterns in a process for manufacturing an image sensor, using FIG. 1A to FIG. 2B. FIG. 1 are plan views of an overlay inspection mark. FIG. 1B illustrates a cross section along a line A-A′ of FIG. 1A.

As illustrated in FIG. 1B, like the general semiconductor lithography process, the overlay management in the image sensor manufacturing process includes measurement of a deviation in an overlay inspection mark, specifically a pattern 1 of a comparison layer and a pattern 2 of a reference layer, using a photoresist formed by an exposure device. Based on the result, a correction value for an overlay error is calculated, and this correction value is applied to a following exposure process in the manufacturing process, to suppress the overlay error.

Generally, the measurement in the overlay inspection device is performed for measuring the deviation of the overlay inspection marks, by simultaneously acquiring the overlay inspection marks formed in the comparison layer and the reference layer as optical images. The overlay measurement is performed usually once in the photolithography process, and performed for a single reference layer. The overlay correction value is calculated to correct the overlay error for the signal layer.

However, the above-described overlay inspection method has a problem that defocus occurs at the time of acquiring the image, when there is a remarkable difference in heights of the inspection marks of the comparison layer and the reference layer.

FIG. 2A and FIG. 2B schematically illustrate a state in which images of an overlay inspection mark is acquired. FIG. 2A and FIG. 2B illustrate a cross section of the overlay inspection mark. An overlay inspection device has an imaging optical system for acquiring an image of the inspection mark, and emits inspection light 7 to a target inspection mark.

As illustrated in FIG. 2A, when the pattern 2 of the reference layer and the pattern 1 of the comparison layer exist in the depth of focus 8 of this optical system, a good inspection image can be acquired from the pattern 2 of the reference layer and the pattern 1 of the comparison layer.

As illustrated in FIG. 2B, when a pattern 3 of the reference layer deviates from the depth of focus, an image blur occurs in the pattern 3 of the reference layer of the acquired image, thus lowering the accuracy of the overlay error measurement.

As described above, it is necessary to measure the overlay of the uppermost wiring layer and the pixels in the manufacturing of the image sensor having the image plane phase detection auto-focus function. This results in a problem of deteriorating the measurement accuracy, if there is a remarkable difference in heights between the inspection marks.

It is necessary to perform overlay inspection for the pixels and the vias (via hole layer) right under the uppermost wiring layer. This results in problems that the number of inspection processes increases and the ordinary factory system cannot achieve calculation of the correction value based on the plurality of inspection results.

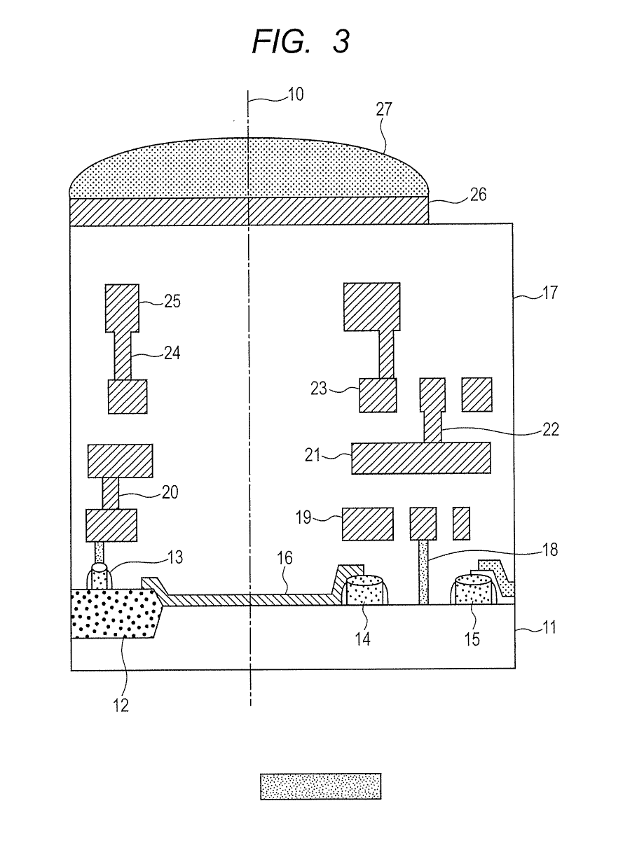

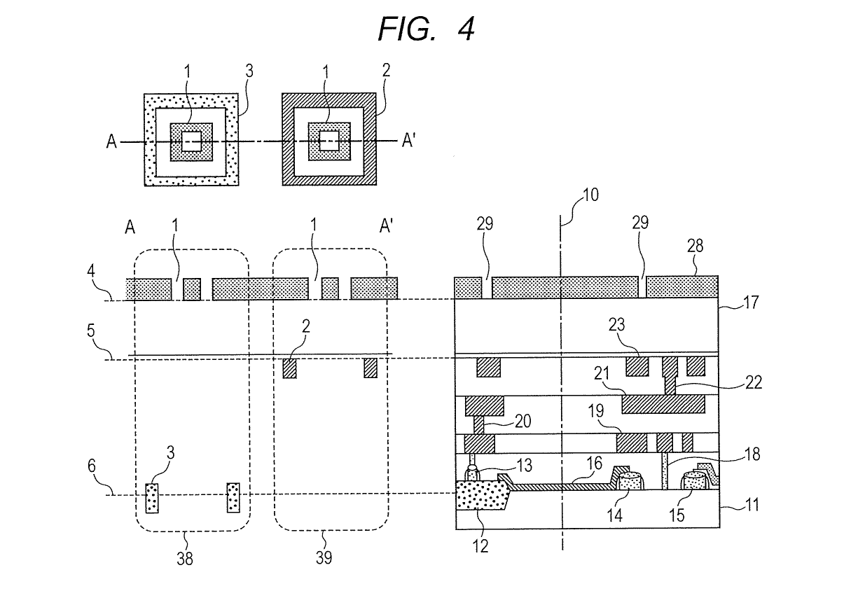

Descriptions will now be made to a method for measuring overlay of patterns in the first embodiment, using FIG. 3 to FIG. 8. FIG. 3 is a cross sectional view illustrating a vertical structure of the image sensor. FIG. 4 illustrates a cross section of the image sensor of FIG. 3, in the middle of the manufacturing process. The left side of FIG. 4 illustrates an overlay inspection mark area, while the right side thereof illustrates an area in which an image sensor is formed.

As illustrated in FIG. 4, in the image sensor of this embodiment, the pattern 3 of the reference layer (lower layer) is formed in an area of an overlay inspection mark A38. This pattern 3 of the reference layer (lower layer) is formed in the same layer as an oxide isolation layer (STI) 12. The pattern 2 of the reference layer (upper layer) is formed in an area of an overlay inspection mark A′39. The pattern 2 of the reference layer (upper layer) is formed in the same layer as an M3 wiring layer 23.

An interlayer insulating film 17 is formed to cover the M3 wiring layer 23 and the pattern 2 of the reference layer (upper layer), on the M3 wiring layer 23 and the pattern 2 of the reference layer (upper layer). Formed on the MS wiring layer 23 and the pattern 2 of the reference layer (upper layer) is a silicon nitride film (SiN film), a silicon carbide (SiC film), or nitrogen addition carbide silicon (SiCN film), which functions as a diffusion preventing film (barrier film) for copper (Cu) used as lower wiring or an etching stopper film at the time of via-etching.

A photoresist film 28 is faulted on the interlayer insulating film 17. A V3 via pattern 29 is formed in the photoresist film 28 in the area where the image sensor is formed. The pattern 1 of the comparison layer is formed in the photoresist film in the area of the overlay inspection mark A38 and the area of the overlay inspection mark A′39.

Now, the overlay inspection is performed for the V3 via pattern 29, the M3 wiring 23, and the oxide isolation (STI) 12, respectively using the pattern 1 of the comparison layer, the pattern 2 of the reference layer (upper layer), and the pattern 3 of the reference layer (lower layer), that are formed in the same layers as the respective patterns.

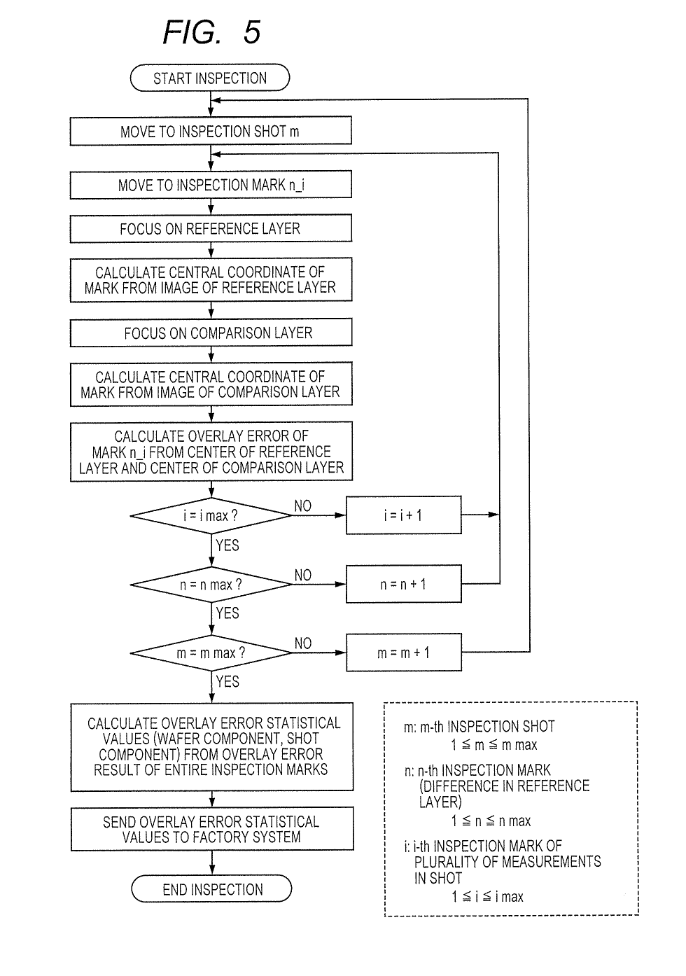

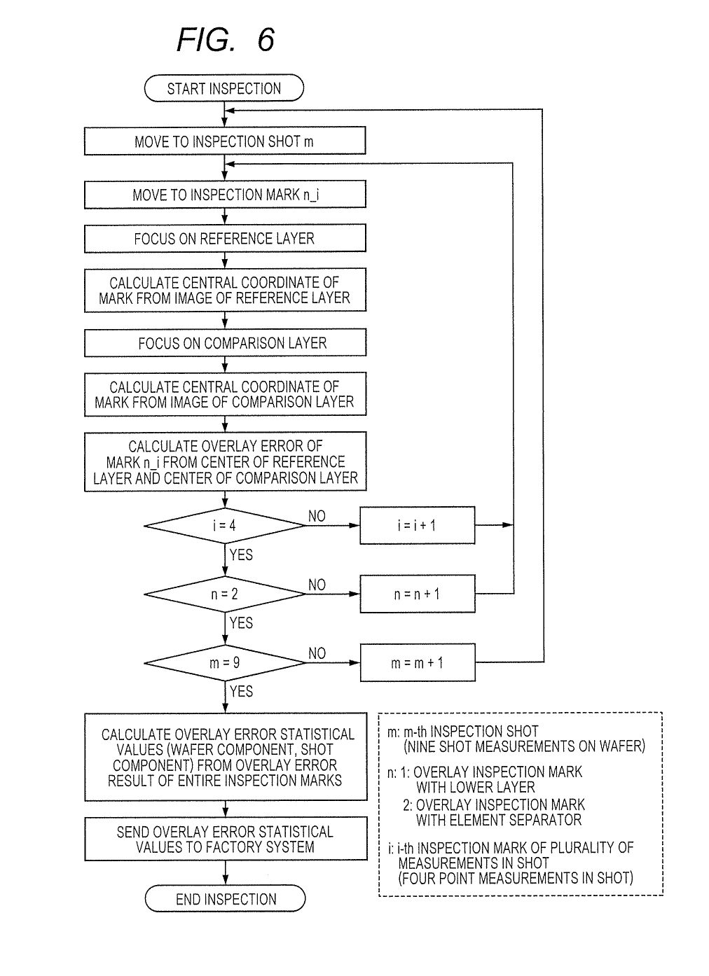

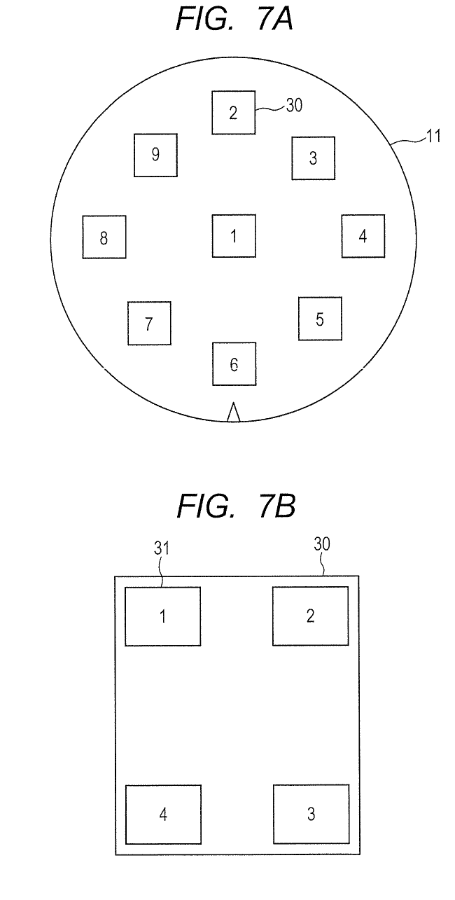

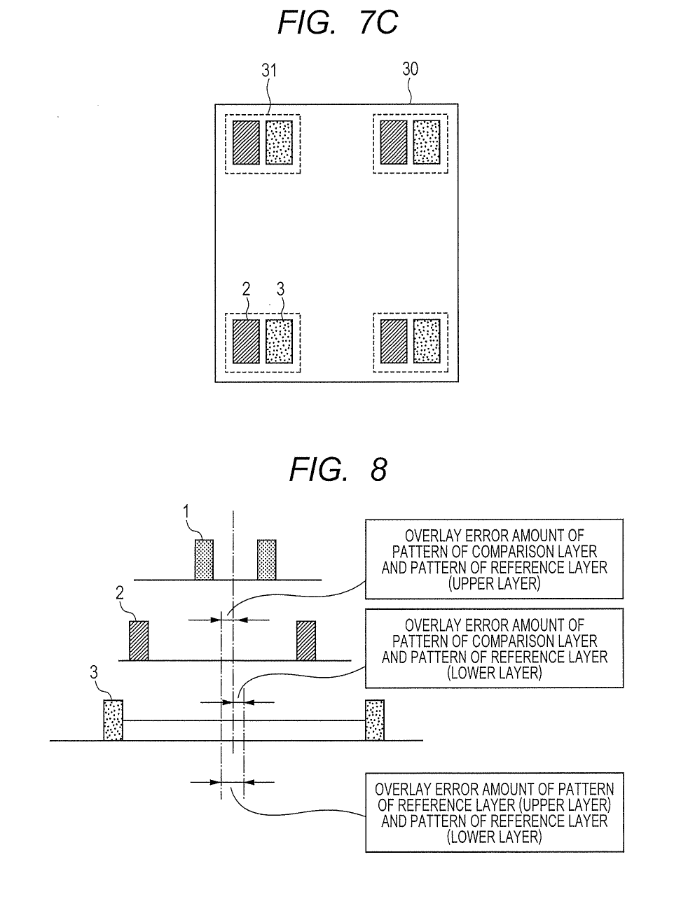

Descriptions will now be made to the overlay inspection method of this embodiment, with reference to FIG. 5 to FIG. 8. FIG. 5 illustrates a pattern overlay inspection flow for patterns, in this embodiment. FIG. 6 illustrates a concrete example of a case in which i=4, n=2, and m=9 in FIG. 5. FIG. 7A to FIG. 7C schematically illustrate a layout of an inspection shot and an inspection mark. FIG. 8 schematically illustrates overlay inspection, using inspection patterns (comparison pattern and reference pattern) provided in a plurality of layers.

As illustrated in FIG. 5, firstly, an inspection optical system is moved to an inspection shot “m” formed on a semiconductor wafer. “m” is an m-th inspection shot formed on the semiconductor wafer. For example, in FIG. 7A, an inspection shot 1 as the 1^{st} inspection shot is laid out in the center of the semiconductor wafer 11.

The system is moved to an inspection mark n_i in the inspection shot “m”. “n” is an n-th inspection mark formed in the inspection shot. For example, in FIG. 7B, the inspection mark 1 as the 1^{st} inspection mark is laid out on the upper left in an inspection shot 30. The inspection marks are formed in different layers. “i” of FIG. 5 is an i-th inspection mark to be measured in a plurality of measurements in the shot.

Subsequently, inspection light is focused on the reference layer, and the central coordinates of the mark (pattern of the reference layer) are calculated using the image of the reference layer. In the example of the image sensor of FIG. 4, for example, focusing is made on the pattern 3 of the reference layer (lower layer) formed in the same layer as the oxide isolation (STI) 12 in the area of the overlay inspection mark A38, and the central coordinates of the pattern 3 of the reference layer (lower layer) are calculated.

After this, inspection light is focused on the comparison layer (pattern of the comparison layer), and the central coordinates of the mark (pattern of the comparison layer) are calculated using the image of the comparison layer. In the example of FIG. 4, focusing is made on the pattern 1 of the comparison layer formed in the photoresist film 28 in the area of the overlay inspection mark A38, and the central coordinates of the pattern 1 of the comparison layer are calculated.

An overlay error amount of the inspection mark n_i is calculated, based on the center of the pattern of the reference layer and the center of the pattern of the comparison layer. In the example of FIG. 4, an overlay error amount of the pattern 3 of the reference layer (lower layer) and the pattern 1 of the comparison layer is calculated, based on the center of the pattern 3 of the reference layer (lower layer) and the center of the pattern 1 of the comparison layer.

The above flow is repeatedly executed until each of “i”, “n”, and “m” reaches the defined maximum value. For example, in the example of FIG. 4, subsequently to the overlay inspection mark A38, focusing is made on the pattern 2 of the reference layer (upper layer) formed in the same layer as the M3 wiring layer 23 in the area of the overlay inspection mark A′39, and the central coordinates of the pattern 2 of the reference layer (upper layer) is calculated. Similarly, focusing is made on the pattern 1 of the comparison layer formed in the photoresist film 28 in the area of the overlay inspection mark A′39, and the central coordinates of the pattern 1 of the comparison layer are calculated. Then, an overlay error amount of the pattern 2 of the reference layer (upper layer) and the pattern 1 of the comparison layer is calculated, based on the center of the pattern 2 of the reference layer (upper layer) and the center of the pattern 1 of the comparison layer.

Finally, a wafer component and a shot component are calculated as statistic values of the overlay error, from the overlay error amounts of the entire inspection marks. The calculated results (overlay error statistic values) are sent to the factory management system, and the inspection is ended.

As described above, in this embodiment, the overlay inspection for the plurality of reference layers is executed in one overlay inspection process. At this time, the images focused respectively on the reference layer and the comparison layer respectively having the inspection marks are acquired, and the overlay error amount of the inspection marks is calculated based on the images. The wafer component and the shot component as the statistic values of the overlay error are calculated based on the overlay error amount of the entire inspection marks.

FIG. 6 to FIG. 7C illustrate a concrete example of the overlay inspection flow of FIG. 5. FIG. 6 illustrates an example, in which the maximum value (max) of “m” is 9, the “n” maximum value (max) is 2, and the “i” maximum value (max) is 4. The number of sample wafer to which the present technique is applied is one. As illustrated in FIG. 7A, nine shots are measured in the wafer. As illustrated in FIG. 7B, four points are measured in one inspection shot. As illustrated in FIG. 7C, the reference patterns formed in different two layers are measured.

FIG. 8 schematically illustrates a method of measuring an overlay error amount, using the method illustrated in FIG. 5 or FIG. 6. Measurement is made on an overlay error amount of the pattern 1 of the comparison layer and the pattern 2 of the reference layer (upper layer). Measurement is made on an overlay error amount of the pattern 1 of the comparison layer and the pattern 3 of the reference layer (lower layer). Calculation is made on an overlay error amount of the pattern of the comparison layer, the pattern of the reference layer (upper layer), and the pattern of the reference layer (lower layer), based on the individually measured overlay error amount of the pattern of the comparison layer and the pattern of the reference layer (upper layer) and the overlay error amount of the pattern of the pattern of the comparison layer and the pattern of the reference layer (lower layer).

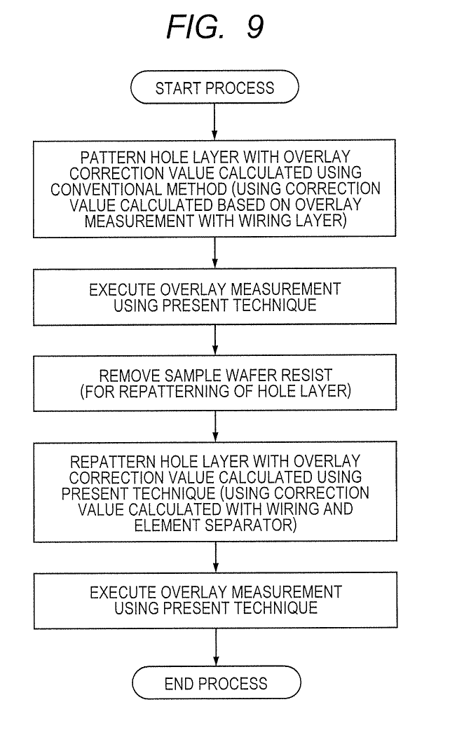

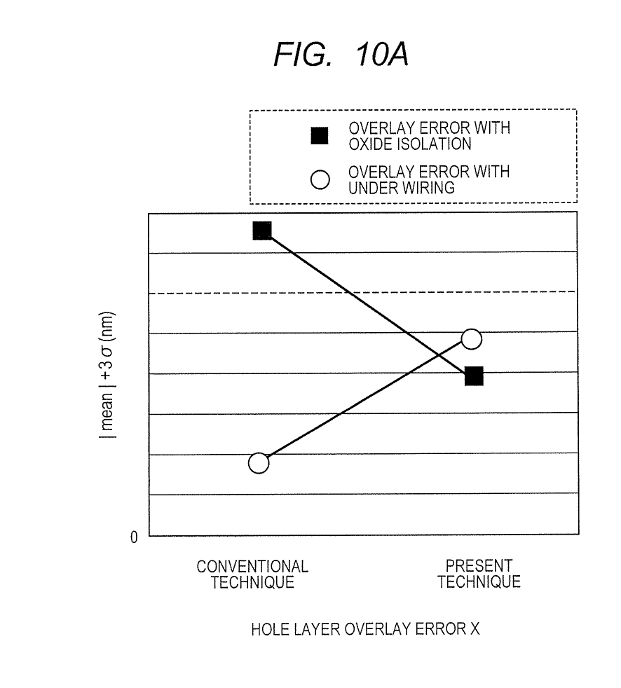

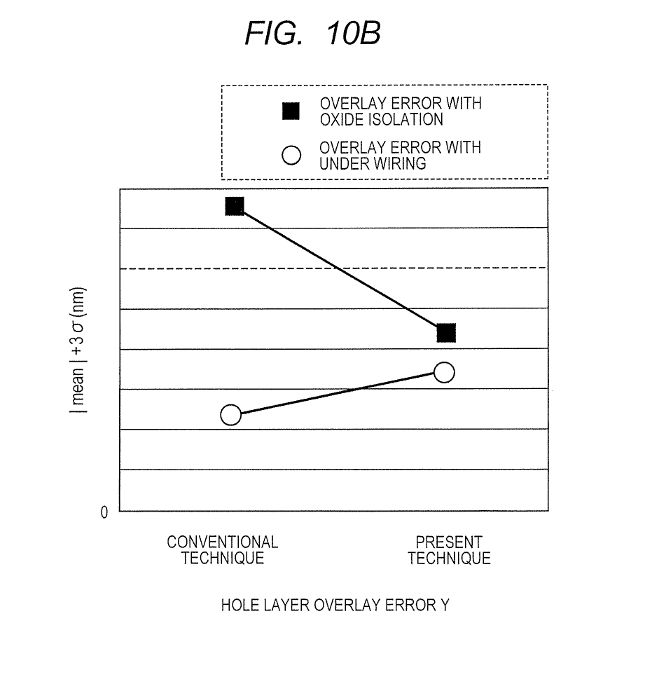

For clear description of the effect of this embodiment, FIG. 10A ad FIG. 10B illustrate the effect of overlay, upon execution of the patterning using a correction value calculated with a conventional technique and the patterning using a correction value calculated with the technique of the present embodiment. FIG. 9 illustrates the flow of the sample wafer process used in the evaluation.

FIG. 10A and FIG. 10B illustrate an overlay error of a case in which overlay correction is performed using a conventional technique on the wafer and a case in which overlay correction is performed using the technique of the present invention. Note that the evaluation has been executed using the structure of the image sensor and the overlay inspection mark, as illustrated in FIG. 4.

As illustrated in FIG. 10A and FIG. 10B, in the conventional technique, the overlay error with the wiring layer is small both in an X direction and a Y direction, because the correction is made with the overlay correction value for the wiring layer. However, in the conventional technique, the overlay error for the oxide isolation is not corrected, thus causing a large overlay error. This difference is caused by the overlay error of the wiring layer as the reference layer and the oxide isolation.

On the other hand, in the technique of this embodiment, the overlay error with the wiring layer and the overlay error with the oxide isolation are approximate values, because an optimum overlay correction value for two reference layers is calculated. As a result, the overlay error with the wiring layers is larger than that of conventional technique. However, the deviation is equalized between both layers, thus attaining a desired effect.

In the conventional technique, the overlay error amount with the oxide isolation exceeds a standard value illustrated in FIG. 10A and FIG. 10B. In the technique of the present embodiment, the overlay error amount with the wiring layer and the overlay error amount with the oxide isolation are both below the standard value.

As described above, according to the overlay inspection method of this embodiment, the overlay measurement is made on the plurality of reference layers in one overlay inspection process for one wafer. In addition, the focusing is made individually on the reference layer and the comparison layer at the time of imaging the entire inspection marks, thereby acquiring the image.

Accordingly, it is possible to suppress deterioration of overlay measurement accuracy, based on a height difference between the reference layers and the comparison layer having the inspection mark. The number of inspection processes can be reduced by executing the overlay measurement for the plurality of reference layers in one inspection process. The overlay error statistic value is calculated while different measurement results of the reference layers are assumed as one population. This results in enabling to calculate the overlay correction value for the plurality of reference layers. That is, even if an overlay error exists between the plurality of reference layers, it is possible to calculate the correction value as an optimum point of compromise for minimizing and equalizing the overlay error amount between the reference layers.

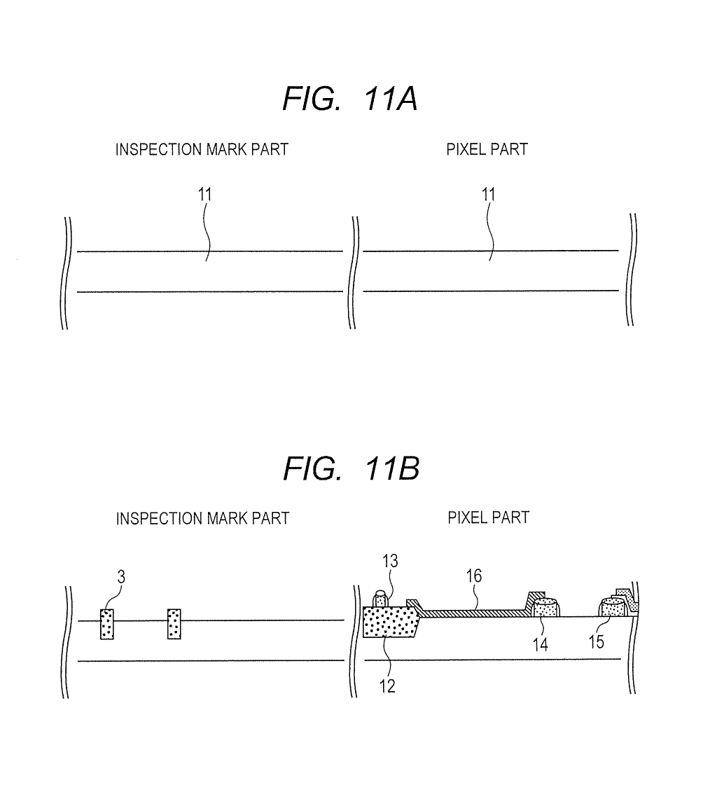

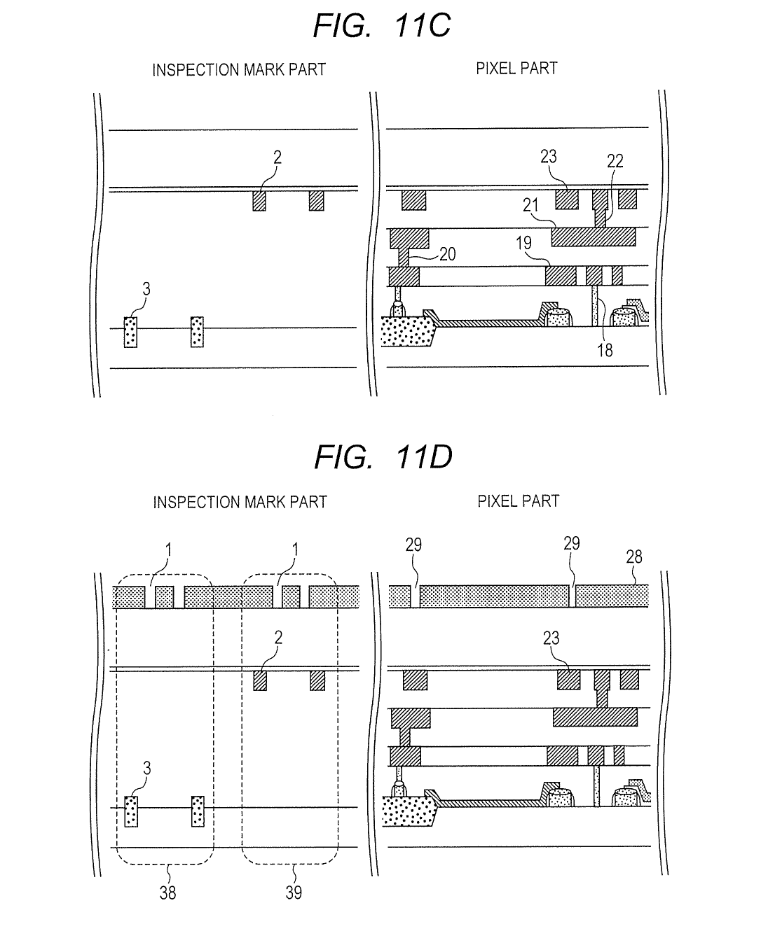

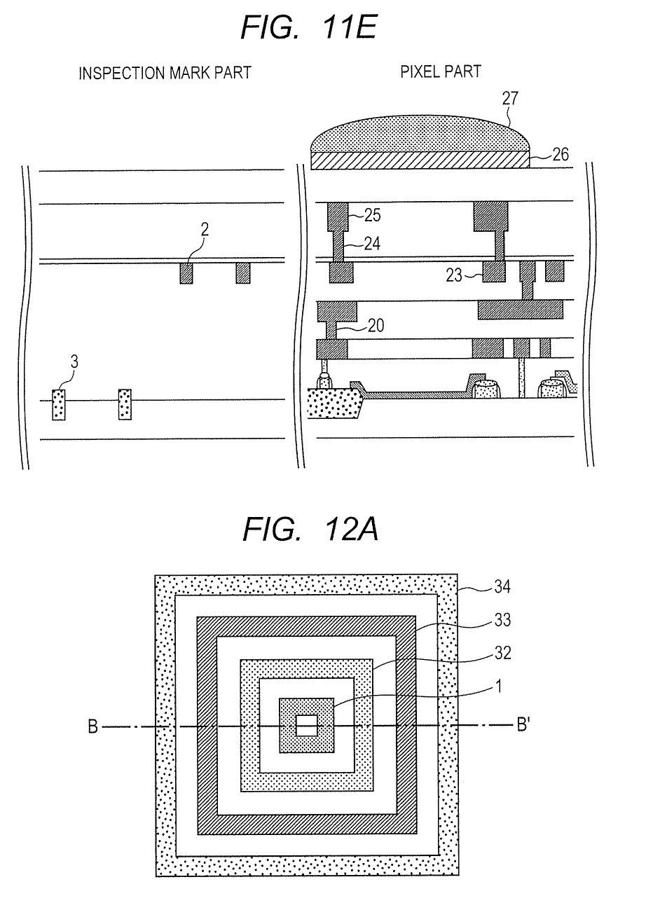

FIG. 11A to FIG. 11E illustrate the manufacturing flow for the image sensor and the overlay inspection mark of FIG. 4.

As illustrated in FIG. 11A, a semiconductor wafer 11 as a substrate is prepared. In the case of a liquid crystal panel, a glass substrate is prepared.

As illustrated in FIG. 113, an oxide isolation (STI) 12, a desired MOS transistor 13, a MOS transistor 14, a MOS transistor 15, and an antireflection film 16 of a pixel area are formed in a pixel part (pixel formation area) on the surface (main surface) of the semiconductor wafer 11. At this time, the pattern 3 of the reference layer is formed in the same layer as the oxide isolation (STI), in the inspection mark part (inspection mark formation area).

Subsequently, as illustrated in FIG. 11C, a process is repeatedly performed for forming the interlayer insulating films, contacts, vias, and wirings, in the pixel part (pixel formation area) on the semiconductor wafer 11, to form a layered structure as illustrated in FIG. 11C. At this time, the pattern 2 of the reference layer is formed in the same layer as the M3 wiring layer 23, in the inspection mark part (inspection mark formation area).

After this, as illustrated in FIG. 11D, the photoresist film 28 is applied. Using a lithography technique, the V3 via pattern 29 is formed in the pixel formation area of the photoresist film 28, and the pattern 1 of the comparison layer are formed in the inspection mark formation area.

The overlay inspection is executed in accordance with the overlay inspection flow of FIG. 5, using the above-formed pattern 1 of the comparison layer, the pattern 2 of the reference layer (upper layer), and the pattern 3 of the reference layer (lower layer). The overlay inspection is performed using the pattern 1 of the comparison layer, the pattern 2 of the reference layer (upper layer), the pattern 3 of the reference layer (lower layer). This enables to perform overlay inspection for the V3 via pattern 29, the M3 wiring 23, and the oxide isolation (STI) 12, formed respectively in the same patterns.

Finally, as illustrated in FIG. 11E, a color filter 26 and a micro lens 27 are formed in the pixel part (pixel formation area), based on M4 wiring 25 as the uppermost wiring.

According to the above-described manufacturing method for the image sensor, the optical axes (central axes) of the respective pixel area defined by the oxide isolation (STI) 12, the M3 wiring 23, and the micro lens 27 can be coaxially formed without deviation. Further, it is possible to improve the distance measurement accuracy of the image sensor having the image plane phase difference auto-focus function.

In this embodiment, the pattern 1 of the comparison layer is formed in the same layer as the V3 via pattern 29 for forming the V3 via 24 right below the M4 wiring 25 as the upper most wiring layer. However, the same effect can be attained with the trench (trench wiring) pattern for forming the M4 wiring 25 as the uppermost wiring layer. The technique of this embodiment may be applied to any layers, without any problem in its functional effect.

### Second Embodiment

FIG. 12A and FIG. 12B illustrate an overlay measurement method for the patterns in the second embodiment . FIG. 12A is a plan view of an overlay inspection mark of this embodiment. FIG. 12B illustrates a cross section along a line B-B′ of FIG. 12A.

In the first embodiment, in the overlay inspection mark, the reference patterns are provided respectively in the different two layers. However, unlike the overlay inspection mark of the first embodiment, in the overlay inspection mark of this embodiment, reference patterns are formed respectively in different three layers. The patterns of the respective layers are formed in one inspection mark part (overlay inspection mark C40).

As illustrated in FIG. 12B, the overlay measurement is performed on a pattern 32 of a reference layer A, a pattern 33 of a reference layer B, and a pattern 34 of a reference layer C, provided respectively in three layers, and also a pattern 1 of one comparison layer. Overlay inspection is performed thereon based on their overlay error amount. As a result, like the first embodiment, it is possible to suppress deterioration of the overlay measurement accuracy, based on a height difference between the reference layer of the inspection mark and the comparison layer. It is also possible to reduce the number of inspection processes by performing the overlay measurement for a plurality of reference layers in one inspection process. The overlay error statistic value is calculated, while different measurement results of the reference layers are assumed as one population. This results in enabling to calculate the overlay correction value for the plurality of reference layers. That is, even if an overlay error exists in the plurality of reference layers, it is possible to calculate the correction value as an optimum point of compromise for minimizing and equalizing the overlay error amount between the reference layers.

In addition, in this embodiment, an image is acquired by focusing on the pattern 1 of the comparison layer 1, the pattern 32 of the reference layer A, the pattern 33 of the reference layer B, and the pattern 34 of the reference layer C. Thus, it is possible to reduce the inspection time since the coordinate shift does not occur between the marks. Another effect is to reduce the occupying area of the inspection mark.

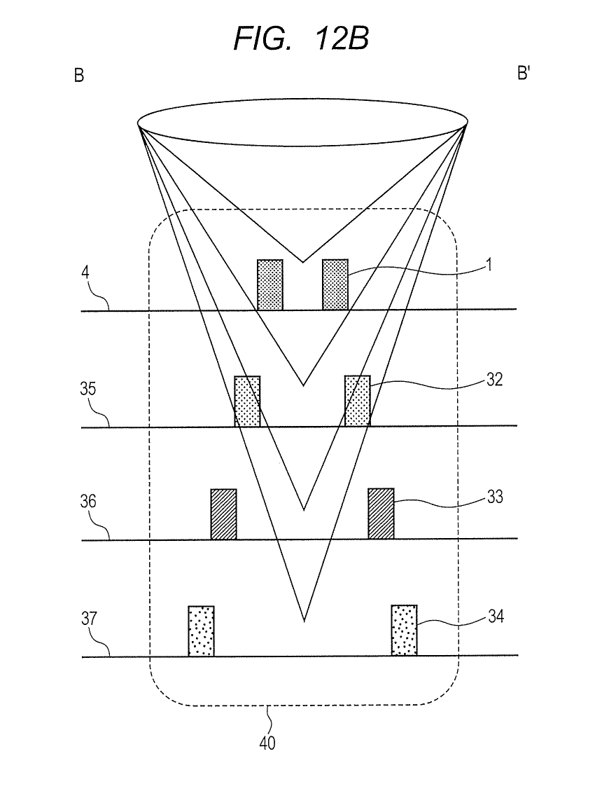

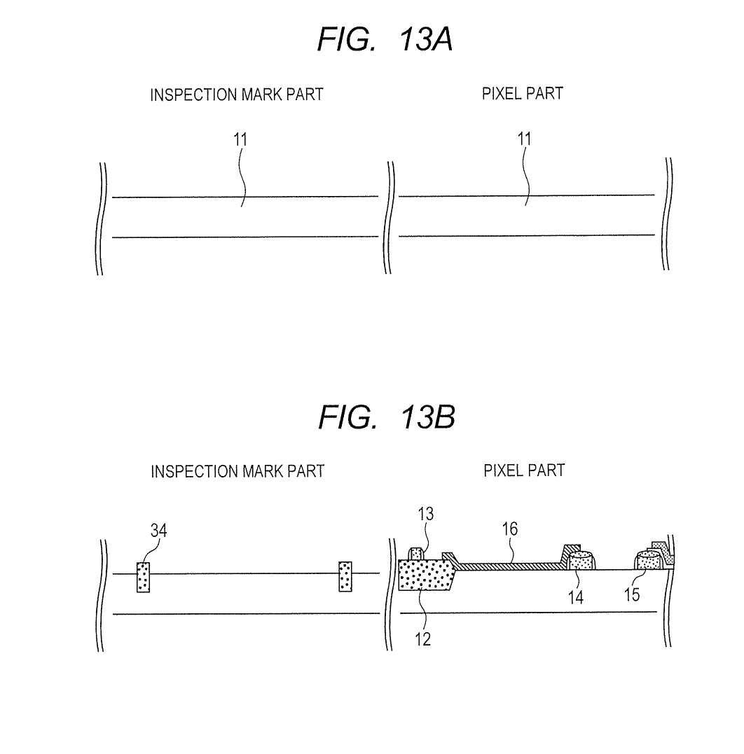

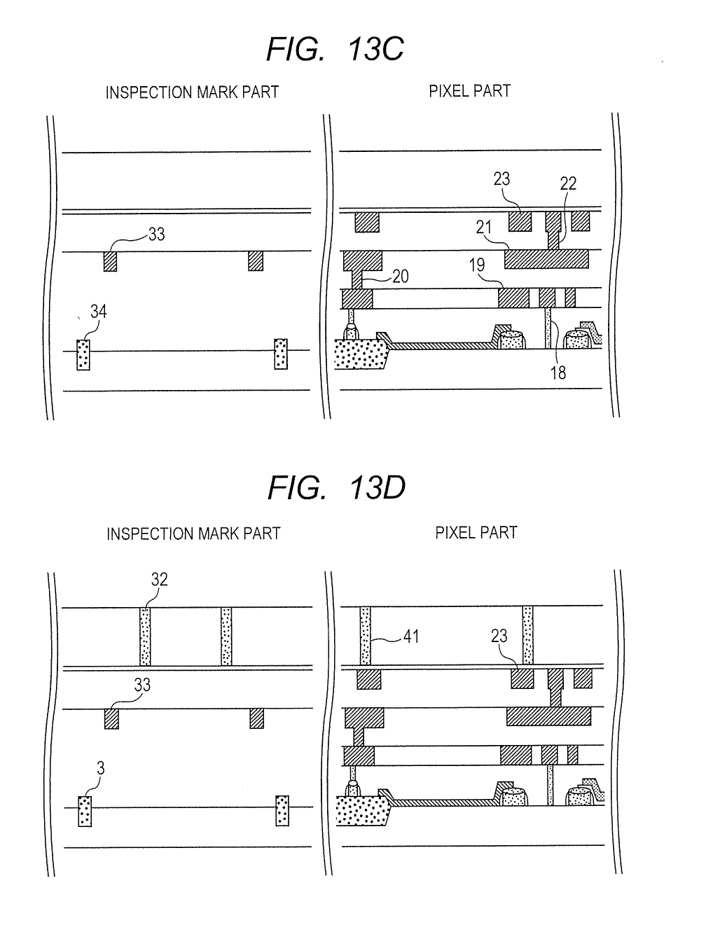

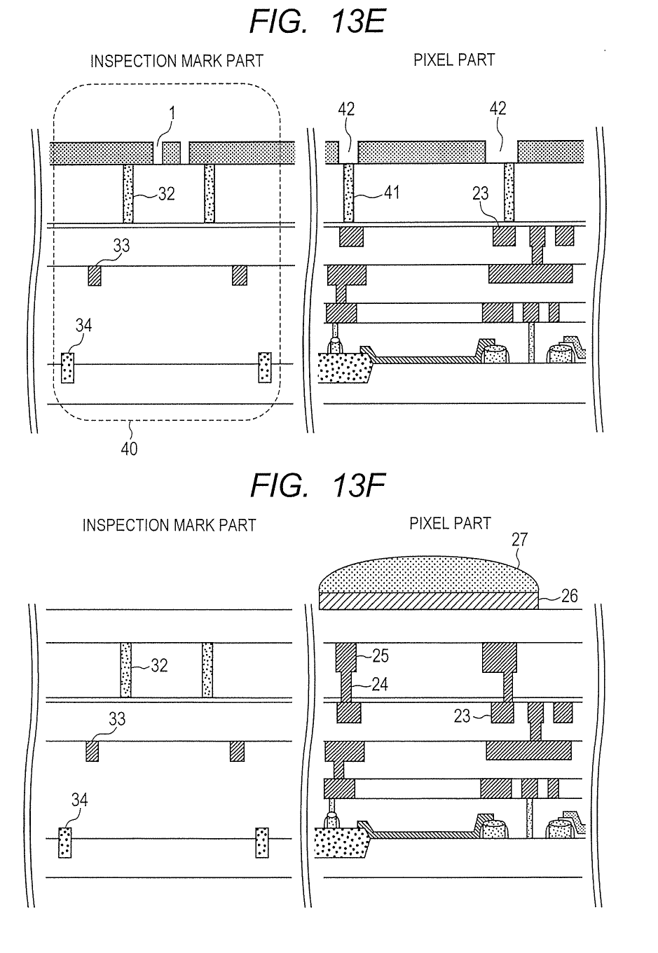

FIG. 13A to FIG. 13F illustrate the manufacturing flow for the image sensor, using the overlay inspection mark illustrated in FIG. 12A and FIG. 12B. Descriptions will now be made to the flow, but the same parts as those of the flow described in FIG. 11A to FIG. 11E in the first embodiment will not be described again.

The processes illustrated in FIG. 13A and FIG. 13B are the same as those illustrated in FIG. 12A and FIG. 12B. As illustrated in FIG. 13B, the pattern 34 of the reference layer C is formed in the same layer as an oxide isolation (STI), in an inspection mark part (inspection mark formation area).

Subsequently, as illustrated in FIG. 13C, the pattern 33 of the reference layer B is formed in the same layer as an M2 wiring layer 21, in the inspection mark part (inspection mark formation area).

After this, as illustrated in FIG. 13D, formed is a via fill 41 for forming a V3 via 24 in a pixel part (pixel formation area). At this time, the pattern 32 of the reference layer A is formed in the same layer as the via fill 41, in the inspection mark part (inspection mark formation area).

Further, as illustrated in FIG. 13E, a photoresist film is applied, an M4 wiring pattern 42 is formed in the pixel formation area of the photoresist film using lithography, and a pattern 1 of the comparison layer is formed in the inspection mark formation area.

The overlay inspection is executed in accordance with the overlay inspection flow of FIG. 5, using the above-formed pattern 1 of the comparison layer, the pattern 32 of the reference layer A, the pattern 33 of the reference layer B, and the pattern 34 of the reference layer C. It is possible to perform high accuracy overlay inspection for the M4 wiring pattern 42, the M2 wiring 21, and the oxide isolation (STI) 12 formed respectively in the same patterns, by performing the overlay inspection using the pattern 1 of the comparison layer, the pattern 32 of the reference layer A, the pattern 33 of the reference layer B, and the pattern 34 of the reference layer C.

Finally, as illustrated in FIG. 13F, a color filter 26 and a micro lens 27 are formed in the pixel part (pixel formation area), based on the M4 wiring 25 as the uppermost wiring.

According to the above-described manufacturing method for the image sensor, the optical axes (central axes) of the respective pixel area defined by the oxide isolation (STI) 12, the M2 wiring 21, the M4 wiring 25, and the micro lens 27, can be coaxially formed without deviation. Further, it is possible to improve the distance measurement accuracy of the image sensor having the image plane phase detection auto-focus function.

In the above embodiments, the descriptions have mainly been made to the image sensor. However, the present invention is not limited to these, and the same functional effects can be attained by forming the same configuration in any other semiconductor devices or liquid crystal panels.

Accordingly, the inventions attained by the present inventors have specifically been described based on the embodiments. However, the present invention is not limited thereto, and needless to say, various changes may possibly be made without departing from the scope thereof.

What is claimed is:

1. A method of manufacturing a semiconductor device, comprising the steps of:
(a) forming a first circuit pattern in a first area of a first layer on a wafer and a first reference pattern in a second area;
(b) forming a second circuit pattern in the first area of a second layer higher than the first layer and a second reference pattern in the second area;
(c) forming a third layer higher than the second layer;
(d) forming a photoresist film on the third layer;
(e) forming a third circuit pattern in the first area of the photoresist film using photolithography and a comparison pattern in the second area;
(f) measuring an overlay error amount of the first reference pattern and the comparison pattern;
(g) measuring an overlay error amount of the second reference pattern and the comparison pattern; and
(h) performing overlay determination of the first reference pattern, the second reference pattern, and the comparison pattern, based on the overlay error amount, acquired in the measuring (f), of the first reference pattern and the comparison pattern and the overlay error amount, acquired in the measuring (g), of the second reference pattern and the comparison pattern.

2. The method of manufacturing the semiconductor device, according to claim 1,
wherein the measuring (f) includes
(f-1) focusing inspection light onto the first reference pattern, and detecting central coordinates of the first reference pattern,
(f-2) focusing inspection light onto the comparison pattern, and detecting central coordinates of the comparison pattern, and
(f-3) calculating an overlay error amount of the first reference pattern and the comparison pattern, based on the central coordinates of the first reference pattern, detected in the focusing (f-1), and the central coordinates of the comparison pattern, detected in the focusing (f-2), and
wherein the measuring (g) includes
(g-1) focusing inspection light onto the second reference pattern, and detecting central coordinates of the second reference pattern,
(g-2) focusing inspection light onto the comparison pattern, and detecting central coordinates of the comparison pattern, and
(g-3) calculating an overlay error amount of the second reference pattern and the comparison pattern, based on the central coordinates of the second reference pattern, detected in the focusing (g-1), and the central coordinates of the comparison pattern, detected in the focusing (g-2).

3. The method of manufacturing the semiconductor device, according to claim 1,
wherein the first circuit pattern is an oxide isolation.

4. The method of manufacturing the semiconductor device, according to claim 1,
wherein the second circuit pattern is a via for coupling wiring patterns or wirings of different layers.

5. The method of manufacturing the semiconductor device, according to claim 1,
wherein the third circuit pattern formed in the photoresist film is a trench wiring pattern for forming an uppermost wiring.

6. A pattern overlay inspection method, comprising the steps of:
measuring an overlay error amount of a first reference pattern formed in a first layer on a substrate and a comparison pattern formed in a photoresist film;
measuring an overlay error amount of a second reference pattern formed in a second layer different from the first layer and the comparison pattern formed in the photoresist film; and
performing overlay determination of the first reference pattern, the second reference pattern, and the comparison pattern, based on the overlay error amount of the first reference pattern and the comparison pattern and the overlay error amount of the second reference pattern and the comparison pattern.

7. The pattern overlay inspection method according to claim 6, comprising the steps of:
focusing inspection light onto the first reference pattern, and detecting central coordinates of the first reference pattern;
focusing inspection light onto the second reference pattern, and detecting central coordinates of the second reference pattern;
focusing inspection light onto the comparison pattern, and detecting central coordinates of the comparison pattern; and
calculating an overlay error amount of the first reference pattern, the second reference pattern, and the comparison pattern, based on the central coordinates of the first pattern, the central coordinates of the second reference pattern, and the central coordinates of the comparison pattern.

8. The pattern overlay inspection method according to claim 6,
wherein the first layer is lower than the second layer.

9. The pattern overlay inspection method according to claim 6,
wherein the substrate is a semiconductor wafer, and
wherein the first layer is same as a layer where an oxide isolation is formed.

10. The pattern overlay inspection method according to claim 6,
wherein the second layer is same as a layer where a via for coupling metal wirings or wirings of different layers is formed.

11. The pattern overlay inspection method according to claim 6,
wherein a trench wiring pattern for forming an uppermost wiring is formed in the photoresist film.

12. A semiconductor device comprising:
a first reference pattern formed in same layer as a first circuit pattern;
a second reference pattern formed in same layer as a second circuit pattern higher than the first circuit pattern; and
a third reference pattern formed in same layer as a third circuit pattern higher than the second circuit pattern, and
wherein the first reference pattern, the second reference pattern, and the third reference pattern are overlay inspection patterns for overlay of the first circuit pattern, the second circuit pattern, and the third circuit pattern.

13. The semiconductor device according to claim 12,
wherein the first reference pattern, the second reference pattern, and the third reference pattern are formed in same inspection pattern area, in a cross section of the semiconductor device.

14. The semiconductor device according to claim 12,
wherein the first circuit pattern is an oxide isolation,
wherein the second circuit pattern is a metal wiring, and
wherein the third circuit pattern is a via for coupling wirings of different layers.
